(19) United States
(12) Patent Application Publication
(10) Pub. No.: US 2009/0151984 A1
(43) Pub. Date: Jun. 18, 2009

(54) Composite resin molded article, laminate, multi-layer circuit board, and electronic device

(75) Inventor: Makoto Fujimura, Tokyo (JP)

Correspondence Address: BIRCH STEWART KOLASCH & BIRCH, PO BOX 747, FALLS CHURCH, VA, 22040-0747, US

(73) Assignee: ZEON CORPORATION, TOKYO (JP)

(21) Appl. No.: 11/990,912

(22) PCT Filed: Aug. 25, 2006
(86) PCT No.: PCT/JP2006/316727

§ 371 Date: Sep. 12, 2008

(30) Foreign Application Priority Data
Aug. 26, 2005 (JP) 2005-245720

(51) Int. Cl. H05K 1/00; B32B 5/02; B05D 3/02; B32B 27/04; B32B 37/10; H05K 3/02

(52) U.S. Cl. 174/250; 442/59; 427/389.9; 428/221; 156/308.2; 427/97.1

(57) ABSTRACT

A composite resin molded article produced by impregnating cloth made from long fibers of a liquid crystal polymer with a curable resin composition which comprises a polymer (A) and a curing agent (B), the polymer (A) having a weight average molecular weight of 10,000 to 250,000 and containing 5 to 60 mol % of a carboxyl group or a carboxylic anhydride group; a method for manufacturing the composite resin molded article; a cured product produced by curing the composite resin molded article; a laminate made by laminating a substrate having a conductive layer (I) on the surface and an electrical insulating layer made of the cured product; a method for manufacturing the laminate; a multilayer circuit board comprising the laminate and a conductive layer (II) formed on an electrical insulating layer of the laminate; a method for manufacturing the circuit board; and an electronic device having the multilayer circuit board are provided. The composite resin molded article and the cured product thereof have excellent flame retardancy, electric insulation properties, and crack resistance, and generates only a very small amount of toxic substances during incineration. The laminate and multilayer circuit board have a low thermal expansion and a high modulus of elasticity. The conductive layer (II) exhibits high adhesion to a smooth electrical insulating layer, even if conductive layer (II) is formed on the electrical insulating layer by a deposition method and thus possesses high reliability. The multilayer circuit board has excellent electrical properties, and therefore can be used suitably as a substrate for a semiconductor device such as a CPU and memory, as well as other surface-mounted components in electronic devices.

### TECHNICAL FIELD

The present invention relates to a composite resin molded article which has excellent flame retardancy, electric insulation properties, and crack resistance, and produces only a very small amount of toxic substances during incineration, a method for manufacturing the composite resin molded article, a cured product produced by curing the composite resin molded article, a laminate produced by laminating a substrate and an electrical insulating layer of the cured product, a method for manufacturing the laminate, a multilayer circuit board produced by forming a conductive layer on the electrical insulating layer of the laminate, a method for manufacturing the multilayer circuit board, and an electronic device having the multilayer board.

### BACKGROUND ART

Along with miniaturization, multifunctionalization, and speeding-up of communication of electronic devices in recent years, a circuit board used for electronic devices is demanded to have a higher density and higher precision. In order to satisfy this demand, use of a multilayer circuit board is rapidly increasing.

A multilayer circuit board is generally obtained by laminating an electrical insulating layer on an internal layer substrate, which is made from an electrical insulating layer and a conductive layer formed on the surface of the electrical insulating layer, and forming a conductive layer on the electrical insulating layer. Several layers of the electrical insulating layer and the conductive layer may be laminated, as required.

When the conductive layer of such a multilayer circuit board has a high density pattern, the conductive layer and the substrate generate a large amount of heat. For this reason, improved flame retardancy is demanded for an electrical insulating layer.

As a method for improving the flame retardancy of an electrical insulating layer, a method for incorporating a flame retardant such as a halogen-containing flame retardant in the electrical insulating layer has been known (Patent Document 1).

However, the halogen-containing flame retardant contained in the electrical insulating layer is thermally decomposed and generates halogen-containing toxic substances when used multilayer circuit boards are incinerated. In addition, the electrical insulating layer containing a halogen-containing flame retardant has insufficient strength. The electrical insulating layer may be cracked or its electrical properties may be impaired, when an impact or a heat history is applied. As a method for increasing the strength of the electrical insulating layer, a method for reinforcing the electrical insulating layer using glass cloth is known. This method, however, further impairs the electrical properties. In addition, there is a case in which flame retardancy is insufficient due to inhomogeneous dispersion of the flame retardant in the electrical insulating layer.

As a method for forming the electrical insulating layer, a method using an adhesive sheet for a multilayer circuit board is known. For example, a method for impregnating nonwoven fabric of a liquid crystal polyester with a resin composition containing an epoxy resin which has a biphenyl structure and a novolak structure, an acrylonitrile-butadiene rubber, and a heat-curing agent as essential components, drying, and half-curing the resin-impregnated nonwoven fabric is proposed in Patent Documents 2.

However, the electrical properties such as the dielectric constant and the dielectric loss tangent of the electrical insulating layer produced by using the adhesive sheet for a multilayer circuit board obtained by this method are insufficient. And it is difficult to form a high-density fine wiring on the obtained electrical insulating layer.

### [Patent Document 1] JP-A-2-255848

### [Patent Document 2] JP-A-2005-175265

### DISCLOSURE OF THE INVENTION

### Problems to be Solved by the Invention

The present invention has been achieved in view of the above-mentioned problems in general technology and has an object of providing a composite resin molded article which has excellent flame retardancy, electric insulation properties, and crack resistance, and produces only a very small amount of toxic substances during incineration, a cured product produced by curing the composite resin molded article, a laminate produced by laminating a substrate and an electrical insulating layer of the cured product, a method for manufacturing the laminate, a multilayer circuit board produced by forming a conductive layer on the electrical insulating layer of the laminate, a method for manufacturing the multilayer circuit board, and an electronic device having the multilayer board.

### Means for Solving the Problem

As a result of extensive studies in order to solve the above-mentioned problems, the inventors of the present invention have found that a cured product of a composite resin molded article produced by impregnating a cloth made from long fibers of a liquid crystal polymer with a curable resin composition which comprises a polymer having a specific molecular weight and containing a specific amount of a carboxyl group or a carboxylic anhydride group and a curing agent has excellent flame retardancy, electric insulation properties, and crack resistance, and produces only a very small amount of toxic substances during incineration. This finding has led to the completion of the present invention.

According to a first aspect of the present invention, there is provided a composite resin molded article which is produced by impregnating a cloth made from long fibers of a liquid crystal polymer with a curable resin composition which comprises a polymer (A), having a weight average molecular weight of 10,000 to 250,000 and containing 5 to 60 mol % of a carboxyl group or a carboxylic anhydride group, and a curing agent (B).

In the composite resin molded article of the present invention, the polymer (A) is preferably an alicyclic olefin polymer, the cloth made from long fibers of a liquid crystal polymer has preferably a weight per unit area of 3 to 55 g/m², and the liquid crystal polymer is preferably a wholly aromatic polyester.

According to a second aspect of the present invention, there is provided a method for manufacturing a composite resin molded article comprising impregnating a cloth made from long fibers of a liquid crystal polymer with a curable resin varnish which comprises a polymer (A) having a weight average molecular weight of 10,000 to 250,000 and containing 5 to 60 mol % of a carboxyl group or a carboxylic anhydride group, a curing agent (B), and an organic solvent, and drying the varnish-impregnated cloth.

According to a third aspect of the present invention, there is provided a cured product produced by curing the composite resin molded article.

According to a fourth aspect of the present invention, there is provided a laminate prepared by laminating a substrate having a conductive layer (I) on the surface and an electrical insulating layer made of the cured product of the present invention.

According to a fifth aspect of the present invention, there is provided a method for preparing the laminate of the present invention comprising forming an electrical insulating layer on a substrate having a conductive layer (I) on the surface by causing the composite resin molded article of the present invention to adhere to the substrate by heat-pressing.

According to a sixth aspect of the present invention, there is provided a multilayer circuit board comprising a conductive layer (II) on the electrical insulating layer of the laminate of the present invention.

According to a seventh aspect of the present invention, there is provided a method for manufacturing the multilayer circuit board of the present invention comprising a step of forming a conductive layer (II) on the electrical insulating layer of the laminate of the present invention by a plating method.

According to an eighth aspect of the present invention, there is provided an electronic device comprising the multilayer circuit board of the present invention.

### BEST MODE FOR CARRYING OUT THE INVENTION

### 1) Composite Resin Molded Article and Method for Producing Same

The composite resin molded article of the present invention is obtained by impregnating a cloth made from long fibers of a liquid crystal polymer with a curable resin composition which comprises a polymer (A) having a weight average molecular weight of 10,000 to 250,000 and containing 5 to 60 mol % of a carboxyl group or a carboxylic anhydride group (these groups are hereinafter referred to from time to time collectively as “carboxyl group and the like”) and a curing agent (B).

### (1) Polymer (A)

The polymer forming the skeleton of the polymer (A) used in the present invention, that is, the polymer with a structure in which the carboxyl group and the like are replaced with hydrogen or the polymer from which the carboxyl group and the like have been eliminated is not particularly limited inasmuch as such a polymer has a weight average molecular weight of 10,000 to 250,000 and contains 5 to 60 mol % of carboxyl group and the like.

As examples of the polymer (A), an epoxy resin, a maleimide resin, an acrylic resin, a methacrylic resin, a diallylphthalate resin, a triazine resin, an alicyclic olefin polymer, an aromatic polyether polymer, a benzocyclobutene polymer, a cyanate ester polymer, and a polyimide resin can be given. These polymers may be used either alone or in combination of two or more.

Of these, due to excellent electrical properties such as a dielectric constant and a dielectric loss tangent, at least one polymer selected from the group consisting of an alicyclic olefin polymer, an aromatic polyether polymer, a benzocyclobutene polymer, a cyanate ester polymer, and a polyimide resin is preferable, with an alicyclic olefin polymer and an aromatic polyether polymer being more preferable, and an alicyclic olefin polymer being still more preferable.

In the present invention, the alicyclic olefin polymer refers collectively to a homopolymer and copolymer of an alicyclic compound having a carbon-carbon unsaturated bond (hereinafter referred to as “an alicyclic olefin”), and derivatives thereof (hydrogenation product and the like). Either an addition polymer or a ring-opening polymer is included.

As specific examples of the alicyclic olefin polymer, a ring-opening polymer of a norbornene monomer and a hydrogenated product thereof, an addition polymer of a norbornene monomer, an addition polymer of a norbornene monomer and a vinyl compound, a monocyclic cycloalkene polymer, an alicyclic conjugated diene polymer, a vinyl-based alicyclic hydrocarbon polymer and a hydrogenated product thereof, and polymers provided with a structure equivalent to the alicyclic olefin polymer by formation of an alicyclic ring by hydrogenation after polymerization such as an aromatic-ring hydrogenated product of an aromatic olefin polymer can be given.

Of these, the ring-opening polymer of a norbornene monomer and a hydrogenated product thereof, the addition polymer of a norbornene monomer, the addition polymer of a norbornene monomer and a vinyl compound, and the aromatic ring hydrogenated product of an aromatic olefin polymer are preferable, with the hydrogenated product of the ring-opening polymer of a norbornene monomer being particularly preferable.

When the polymer (A) is an alicyclic olefin polymer, the carboxyl group and the like may either directly bond to a carbon atom which forms an alicyclic structure or bond via another divalent group such as a methylene group, an oxy group, an oxycarbonyloxyalkylene group, or a phenylene group.

The weight average molecular weight (Mw) of the polymer (A) used in the present invention is usually 10,000 to 250,000, preferably 15,000 to 150,000, and more preferably 20,000 to 100,000.

If the Mw of the polymer (A) is too small, the strength of the resulting electrical insulating layer is insufficient. In addition, the electrical insulation properties may be poor. If the Mw is too large, mutual solubility of the polymer (A) and the curing agent (B) may decrease and surface roughness of the electrical insulating layer may increase, resulting in a possible decrease of circuit pattern precision.

The Mw of the polymer (A) is measured by gel permeation chromatography (GPC) and determined as a polystyrene-reduced value.

In order to adjust the Mw of the polymer (A) in the above range, a common method such as a method for adding 0.1 to 10 mol % of a molecular weight adjusting agent such as a vinyl compound or a diene compound to the total amount of the monomers when the alicyclic olefin polymer is produced using a titanium catalyst or a tungsten catalyst can be used. As specific examples of such a molecular weight adjusting agent, as vinyl compounds, α-olefin compounds such as 1-butene, 1-pentene, 1-hexene, and 1-octene; styrene compounds such as styrene and vinyltoluene; ether compounds such as ethyl vinyl ether, isobutyl vinyl ether, and allyl glycidyl ether; halogen-containing vinyl compounds such as allyl chloride; other vinyl compounds such as allyl acetate, allyl alcohol, glycidyl methacrylate, and acrylamide; and the like can be given. As examples of the diene compounds, non-conjugated diene compounds such as 1,4-pentadiene, 1,5-hexadiene, 1,6-heptadiene, 2-methyl-1,4-pentadiene, and 2,5-dimethyl-1,5-hexadiene; and conjugated diene compounds such as 1,3-butadiene, 2-methyl-1,3-butadiene, 2,3-dimethyl-1,3-butadiene, 1,3-pentadiene, and 1,3-hexadiene can be given.

The polymer (A) used in the present invention has an Mw of the above-mentioned range and a content of a carboxyl group and the like of 5 to 60 mol %, preferably 10 to 50 mol %, and still more preferably 15 to 40 mol %. The content of the carboxyl group and the like refers to the number of moles of the carboxyl group and the like contained in the polymer to the total number of monomer units in the polymer.

If the content of the carboxyl group and the like of the polymer (A) is too small, the plating adhesion and heat resistance may decrease; if the content is too large, electrical insulating properties may decrease.

The content of the carboxyl group and the like of the polymer (A) can be determined by ¹H-NMR spectrum measurement of the polymer (A).

The acid number of the polymer (A) used in the present invention is usually 10 to 400 mg KOH/g, and preferably 50 to 400 mg KOH/g. The term “acid number” refers to the amount (mg) of potassium hydroxide (KOH) required for neutralizing the carboxyl group and the like contained in 1 g of a sample.

If the acid number is too small, the plating adhesion and heat resistance may decrease; if the acid number is too large, electrical insulating properties may decrease.

The acid number of the polymer (A) can be determined by the method according to JIS K0070. Specifically, the polymer (A) is dissolved in tetrahydrofuran (THF) and the solution is titrated with a solution of tetra-n-butylammonium hydroxide ((n-C₄H₉)₄N⁺OH⁻) of a predetermined concentration using phenolphthalein specified in JIS K 8001, 4.3, as an indicator. The amount (mg) of potassium hydroxide required to neutralize the carboxyl group and the like contained in 1 g of the sample can be calculated based on the result obtained by the titration.

There is a correlation between the content of the carboxyl group and the like and the acid number of the polymer (A). In general, the larger the content of the carboxyl group and the like, the larger the acid number; and the smaller the content of the carboxyl group and the like, the smaller the acid number.

There are no specific limitations to the method for limiting the content of the carboxyl group and the like (or the acid number) of the polymer (A) to the above range. For example, (i) a method for homopolymerizing an alicyclic olefin monomer containing the carboxyl group and the like or copolymerizing an alicyclic olefin monomer containing the carboxyl group and the like with other copolymerizable monomers such as ethylene, 1-hexene, or 1,4-hexadiene; (ii) a method for introducing the carboxyl group and the like to an alicyclic olefin polymer which does not contain the carboxyl group and the like by grafting a compound having the carboxyl group and the like, which has a carbon-carbon unsaturated bond, in the presence of a radical initiator, for example; and (iii) a method for polymerizing a norbornene monomer having a group which can be a precursor of the carboxyl group such as a carboxylic acid ester group, and converting the precursor group into the carboxyl group by hydrolysis and the like can be given.

As the carboxyl group-containing alicyclic olefin monomer used in the above method (i), 8-hydroxycarbonyltetracyclo[4.4.0.1^{2,5}.1^{7,10}]dodec-3-ene, 5-hydroxycarbonylbicyclo[2.2.1]hept-2-ene, 5-methyl-5-hydroxycarbonylbicyclo[2.2.1]hept-2-ene, 5-carboxymethyl-5-hydroxycarbonylbicyclo[2.2.1]hept-2-ene, 8-methyl-8-hydroxycarbonyltetracyclo[4.4.0.1^{2,5}.1^{7,10}]dodec-3-ene, 8-carboxymethyl-8-hydroxycarbonyltetracyclo[4.4.0.1^{2,5}1^{7,10}]dodec-3-ene, 5-exo-6-endo-dihydroxycarbonylbicyclo[2.2.1]hept-2-ene, 8-exo-9-endo-dihydroxycarbonyltetracyclo[4.4.0.1^{2,5}.1^{7,10}]dodec-3-ene, and the like can be given.

As examples of the carboxylic acid anhydride group-containing alicyclic olefin monomer used in the above method (i), bicyclo[2.2.1]hept-2-ene-5,6-dicarboxylic acid anhydride, tetracyclo[4.4.0.1^{2,5}.1^{7,10}]dodec-3-ene-8,9-dicarboxylic acid anhydride, and hexacyclo[6.6.1.1^{3,6}.1^{10,13}.0^{2,7}.0^{9,14}]heptadec-4-ene-11,12-dicarboxylic acid anhydride can be given.

As specific examples of the monomers for obtaining the alicyclic olefin polymer which does not have the carboxyl group and the like used for the method (ii), bicyclo[2.2.1]hept-2-ene (common name: norbornene), 5-ethylbicyclo[2.2.1]hept-2-ene, 5-butylbicyclo[2.2.1]hept-2-ene, 5-ethylidenebicyclo[2.2.1]hept-2-ene, 5-methylidenebicyclo[2.2.1]hept-2-ene, 5-vinylbicyclo[2.2.1]hept-2-ene, tricyclo[4.3.0.1^{2,5}]deca-3,7-diene (common name: dicyclopentadiene), tetracyclo[8.4.0.1^{11,14}.0^{2,8}]tetradeca-3,5,7,12,11-tetraene, tetracyclo[4.4.0.1^{2,5}.1^{7,10}]dec-3-ene (common name: tetracyclododecene), 8-methyltetracyclo[4.4.0.1^{2,5}.1^{7,10}]dodec-3-ene, 8-ethyltetracyclo[4.4.0.1^{2,5}.1^{7,10}]dodec-3-ene, 8-methylidenetetracyclo[4.4.0.1^{2,5}.1^{7,10}]dodec-3-ene, 8-ethylidenetetracyclo[4.4.0.1^{2,5}.1^{7,10}]dodec-3-ene, 8-vinyltetracyclo[4.4.0.1^{2,5}.1^{7,10}]dodec-3-ene, 8-propenyltetracyclo[4.4.0.1^{2,5}.1^{7,10}]dodec-3-ene, pentacyclo[6.5.1.1^{3,6}.0^{2,7}.0^{9,13}]pentadeca-3,10-diene, pentacyclo[7.4.0.1^{3,6}.1^{10,13}.0^{2,7}]pentadeca-4,11-diene, cyclopentene, cyclopentadiene, 1,4-methano-1,4,4a,5,10,10a-hexahydroanthracene, and 8-phenyltetracyclo[4.4.0.1^{2,5}.1^{7,10}]dodec-3-ene can be given.

As examples of the compound having a carbon-carbon unsaturated bond and the carboxyl group and the like used in the method (ii), unsaturated carboxylic acid compounds such as acrylic acid, methacrylic acid, α-ethylacrylic acid, 2-hydroxyethylacrylic acid, 2-hydroxyethylmethacrylic acid, maleic acid, fumaric acid, itaconic acid, endo-cis-bicyclo[2.2.1]hept-5-ene-2,3-dicarboxylic acid, and methyl-endo-cis-bicyclo[2.2.1]hept-5-ene-2,3-dicarboxylic acid; unsaturated carboxylic acid anhydrides such as maleic anhydride, chloromaleic anhydride, butenylsuccinic anhydride, tetrahydrophthalic anhydride, and citraconic anhydride; and the like can be given.

As examples of the norbornene monomer having the group which can be a precursor of the carboxyl group used in the above method (iii), 8-methyl-8-methoxycarbonyltetracyclo[4.4.0.1^{2,5}.1^{7,10}]dodec-3-ene, 5-methoxycarbonylbicyclo[2.2.1]hept-2-ene, and 5-methyl-5-methoxycarbonylbicyclo[2.2.1]hept-2-ene can be given.

The polymer (A) may have a functional group other than the carboxyl group and the like (such a functional group is hereinafter referred to from time to time as “other functional group”). As examples of the other functional group, an alkoxycarbonyl group, a cyano group, a hydroxyl group, an epoxy group, an alkoxyl group, an amino group, an amide group, and an imino group can be given. These other functional groups are used preferably in an amount of 30 mol % or less, more preferably 10 mol % or less, and particularly preferably 1 mol % or less of the amount of the carboxyl group and the like.

Although not particularly limited, the glass transition temperature (Tg) of the polymer (A) used in the present invention is preferably 120 to 300° C. If the Tg is too low, the resulting electrical insulating layer cannot maintain sufficient electric insulation properties at a high temperature; if the Tg is too high, a crack may be produced when a strong impact is applied to the multilayer circuit board and the conductive layer may be damaged.

The polymer (A) used in the present invention has electrical insulating properties.

The volume resistibility of the polymer (A) measured by ASTM D257 is preferably 1×10¹² Ω·cm or more, more preferably 1×10¹³ Ω·cm or more, and particularly preferably 1×10¹⁴ Ω·cm or more.

### (2) Curing Agent (B)

The curing agent (B) used in the present invention is not particularly limited insofar as the curing agent can crosslink the polymer (A) by heating. A compound which can form a crosslinking structure by reacting with the carboxyl group and the like of the polymer (A) is preferable.

As such a curing agent, a polyepoxy compound, a compound having two or more isocyanate groups, a polyamine compound, a compound having two or more hydrazide groups, an aziridine compound, a basic metal oxide, an organic metal halide, and the like can be given. These curing agents may be used either individually or in combination of two or more. A peroxide can also be used as a curing agent.

As examples of the polyepoxy compound, compounds having two or more epoxy groups in a molecule, for example, glycidyl ether epoxy compounds such as a phenol novolak epoxy compound, a cresol novolak epoxy compound, a cresol epoxy compound, a bisphenol A epoxy compound, a bisphenol F epoxy compound, a brominated bisphenol A epoxy compound, a brominated bisphenol F epoxy compound, and a hydrogenated bisphenol A epoxy compound; and polyvalent epoxy compounds such as an alicyclic epoxy compound, a glycidyl ester epoxy compound, a glycidyl amine epoxy compound, and an isocyanurate epoxy compound can be given.

As the compound having two or more isocyanate groups, diisocyanates and triisocyanates having 6 to 24 carbon atoms are preferable. As examples of the diisocyanates, 2,4-tolylenediisocyanate, 2,6-tolylenediisocyanate, 4,4′-diphenylmethanediisocyanate, hexamethylenediisocyanate, and p-phenylenediisocyanate can be given. As examples of the triisocyanates, 1,3,6-hexamethylenetriisocyanate, 1,6,11-undecanetriisocyanate, and bicycloheptanetriisocyanate can be given.

As the polyamine compound, aliphatic polyamine compounds having 4 to 30 carbon atoms and two or more amino groups, aromatic polyamine compounds having two or more amino groups, and the like can be given, and compounds having a non-conjugated nitrogen-carbon double bond such as a guanidine compound are excluded.

Examples of the aliphatic polyamine compound include hexamethylenediamine and N,N′-dicinnamilidene-1,6-hexanediamine.

Examples of the aromatic polyamine compound include 4,4′-methylenedianiline, m-phenylenediamine, 4,4′-diamino diphenyl ether, 4′-(m-phenylenediisopropylidene)dianiline, 4,4′-(p-phenylenediisopropylidene)dianiline, 2,2′-bis[4-(4-aminophenoxy)phenyl]propane, and 1,3,5-benzenetriamine.

As examples of the compound having two or more hydrazide groups, isophthalic acid dihydrazide, terephthalic acid dihydrazide, 2,6-naphthalenedicarboxylic acid dihydrazide, maleic acid dihydrazide, itaconic acid dihydrazide, trimellitic acid dihydrazide, 1,3,5-benzenetricarboxylic acid dihydrazide, and pyromellitic acid dihydrazide can be given.

As examples of the aziridine compound, tris-2,4,6-(1-aziridinyl)-1,3,5-triazine, tris[1-(2-methyl)aziridinyl]phosphinoxide, and hexa[1-(2-methyl)aziridinyl]triphosphatriazine can be given.

As examples of the peroxide, known organic peroxides such as ketone peroxide, peroxyketal, hydroperoxide, diallylperoxide, diacylperoxide, peroxy ester, and peroxy dicarbonate can be given.

Among these curing agents, polyepoxy compounds, particularly bisphenol A epoxy compounds such as bisphenol A bis(propylene glycol glycidyl ether) ether, are preferable due to their moderate reactivity with the polymer (A) and capability of producing composite resin molded articles which can be easily melted, processed, and laminated.

The amount of the curing agent (B) to be used is usually 1 to 100 parts by weight, preferably 5 to 80 parts by weight, and still more preferably 10 to 50 parts by weight for 100 parts by weight of the polymer (A).

### (3) Curing Accelerator

It is preferable for the curable resin composition used in the present invention to further comprise a curing accelerator from the viewpoint of easily obtaining a cured product having heat resistance. For example, when a polyepoxy compound is used as the curing agent (B), a curing accelerator such as a tertiary amine compound or a trifluoroboron complex is suitably used. A tertiary amine compound is particularly preferable due to the capability of promoting the properties of laminating layers as to minute wiring, insulation resistance, heat resistance, and chemical resistance. As examples of the tertiary amine compound, chain-like tertiary amine compounds such as benzylmethylamine, triethanolamine, triethylamine, tributylamine, tribenzylamine, and dimethylformamide; nitrogen-containing heterocyclic compounds such as pyrazoles, pyridines, pyrazines, pyrimidines, indazoles, quinolines, isoquinolines, imidazoles and triazoles can be given. Of these, imidazoles, particularly substituted imidazole compounds having a substituent, are preferable.

As examples of the substituted imidazole compound, alkyl-substituted imidazole compounds such as 2-ethylimidazole, 2-ethyl-4-methylimidazole, bis-2-ethyl-4-methylimidazole, 1-methyl-2-ethylimidazole, 2-isopropyl imidazole, 2,4-dimethylimidazole, and 2-heptadecylimidazole; and imidazole compounds substituted with a hydrocarbon group having a cyclic structure such as an aryl group or an aralkyl group, such as 2-phenylimidazole, 1-benzyl-2-methylimidazole, 1-benzyl-2-ethylimidazole, benzimidazole, 2-ethyl-4-methyl-1-(2′-cyanoethyl)imidazole, 2-ethyl-4-methyl-1-[2′-(3″,5″-diaminotriazinyl)ethyl]imidazole, and 1-benzyl-2-phenylimidazole can be given. These curing accelerators may be used either individually or in combination of two or more. Of these, imidazole compounds substituted with a hydrocarbon group having a cyclic structure are preferable, and 1-benzyl-2-phenylimidazole is particularly preferable.

The amount of the curing accelerator to be used is appropriately determined according to the object of application usually in a range from 0.001 to 30 parts by weight, preferably from 0.01 to 10 parts by weight, and still more preferably from 0.03 to 5 parts by weight for 100 parts by weight of the polymer (A).

(4) Cloth Made from Long-Fibers of Liquid Crystal Polymer

The cloth made from long-fibers of a liquid crystal polymer used in the present invention is a woven fabric or nonwoven fabric in which liquid crystalline polyester filaments are used. The liquid crystalline polyester filament as used herein is a continuous filament obtained by spinning a polymer having an ester bond and showing a liquid crystal state (hereinafter referred to from time to time as “liquid crystal polymer”) by molten extrusion or the like.

As such a liquid crystal polymer, common liquid crystal polyesters and liquid crystal polyester amides obtained from the following compounds (a) to (d) or by copolymerization of a suitable combination of these compounds can be given.

(a) Aromatic or aliphatic dihydroxy compound
(b) Aromatic or aliphatic dicarboxylic compound
(c) Aromatic hydroxycarboxylic acid
(d) Aromatic diamine, aromatic hydroxylamine, or aromatic aminocarboxylic acid

Of these, wholly aromatic polyester having substantially no aliphatic hydrocarbon in the main chain is preferable as the liquid crystal polymer.

The all aromatic polyester can be synthesized by combining monomers such as an aromatic diol, aromatic dicarboxylic acid, and aromatic hydroxycarboxylic acid at various ratios. For example, a copolymer of p-hydroxybenzoic acid and 2-hydroxy-6-naphthoic acid, a copolymer of p-hydroxybenzoic acid or terephthalic acid and 4,4′-dihydroxy biphenyl, and the like can be given.

As examples of the form of the cloth made from long fibers of a liquid crystal polymer, a woven or nonwoven fabric such as a roving cloth, a chopped mat, and a surfacing mat can be given. Of these forms, the woven fabric is preferable from the viewpoint of dimensional stability, and the nonwoven fabric is preferable from the viewpoint of processability. In addition, the woven or nonwoven fabric pressed by a hot roller or the like is also preferable.

In the present invention, in order to provide a product with both the advantage of woven fabric and the advantage of nonwoven fabric, a laminate of the woven fabric and nonwoven fabric may be used. Furthermore, a cloth or microfibril of glass, aramid, polybenzoxazole, or natural cellulosic fiber may be mixed with and incorporated in the cloth of a liquid crystal polymer.

The thickness of the insulated resin layer of the cloth made from long-fibers of a liquid crystal polymer used in the present invention can be arbitrarily changed according to the weight of the cloth per unit area. The weight of the cloth per unit area of the cloth made from long-fibers of a liquid crystal polymer is preferably 3 to 55 g/m², and more preferably 6 to 45 g/m².

If the weight per unit area is too small, the strength of the cloth may be insufficient and it may be difficult to provide a coating layer; if too large, it is difficult to produce an insulated resin layer with a small thickness, making it difficult to control the thickness when a laminate is produced.

As the cloth made from long-fibers of a liquid crystal polymer preferably used in the present invention, a nonwoven fabric of all aromatic polyester fibers highly oriented during spinning by a melt-flow method can be given. “VECRUS” and “VECTRAN” (both manufactured by Kuraray Co., Ltd.) can be given as specific examples.

### (5) Composite Resin Molded Article

The composite resin molded article of the present invention comprises a cloth made from long-fibers of a liquid crystal polymer impregnated with the above curable resin composition.

The composite resin molded article may be either uncured or half-cured. The term “uncured” as used herein refers to a state of the polymer (A), in which the entire amount of the polymer (A) is dissolved in a solvent which can dissolve the polymer (A). The term “half-cured” refers to a state in which the polymer (A) is cured to the extent that the resin can be cured further if heated, preferably a state in which a part (specifically 7 wt % or more) of the polymer (A) is dissolved in a solvent which can dissolve the polymer (A) or a state in which the swelling rate of the composite resin molded article, when dipped in a solvent for 24 hours, is 200% or more of the volume before dipping.

The proportion of the cloth made from long-fibers of a liquid crystal polymer in the composite resin molded article of the present invention is usually 20 to 90 wt %, and preferably 30 to 85 wt %. If the amount of the cloth made from long-fibers of a liquid crystal polymer is too small, flame retardancy may be insufficient; if too large, thickness control during lamination may be difficult.

The proportion of the cloth made from long-fibers of a liquid crystal polymer, when the polymer (A) is uncured, can be determined by, for example, dissolving the composite resin molded article in a solvent which can dissolve the polymer (A), but cannot dissolve the liquid crystal polymer, and measuring insoluble components. Such a proportion can also be determined by calculation using the weight per unit area of the cloth made from long-fibers of a liquid crystal polymer used.

The method for impregnating the cloth made from long-fibers of a liquid crystal polymer with the curable resin composition is not particularly limited. A method for impregnating the cloth made from long-fibers of a liquid crystal polymer with a varnish (a curable resin varnish) prepared by dissolving or dispersing the curable resin composition in an organic solvent is preferably used. When the curable resin composition is used as a varnish, the polymer (A) is preferably soluble in the organic solvent used at ordinary temperature.

As the organic solvent used for preparing the varnish, a solvent having a boiling point of 30 to 250° C. is preferable, with a more preferable solvent having a boiling point of 50 to 200° C. The organic solvent having a boiling point of this range is suitable for drying the product by vaporizing the solvent with heating.

As specific examples of such an organic solvent, an aromatic hydrocarbon solvent such as toluene, xylene, ethylbenzene, and trimethylbenzene; an aliphatic hydrocarbon solvent such as n-pentane, n-hexane, and n-heptane; an alicyclic hydrocarbon solvent such as cyclopentane and cyclohexane; a halogenated hydrocarbon solvent such as chlorobenzene, dichlorobenzene, and trichlorobenzene; a ketone solvent such as methyl ethyl ketone, methyl isobutyl ketone, cyclopentanone, and cyclohexanone; and the like can be given.

The amount of the organic solvent is appropriately determined according to the desired thickness and surface flatness of the composite resin molded article from a range of usually 5 to 70 wt %, preferably 10 to 65 wt %, and still more preferably 20 to 60 wt %.

There are no specific limitations to the method for preparing the varnish. A common method for mixing the polymer (A), the curing agent (B), the organic solvent, and the other optional components is employed.

A magnetic stirrer, a high speed homogenizer, a disperser, a planet stirrer, a biaxial stirrer, a ball mill, a three-roller, and the like can be used as a mixer. The mixing is carried out at a temperature in a range in which a curing reaction by the curing agent (B) does not occur, and preferably lower than the boiling point of the organic solvent.

There are no specific limitations to the method for impregnating cloth made from long-fibers of a liquid crystal polymer with the varnish. As a method for applying the varnish to the cloth made from long-fibers of a liquid crystal polymer, dip coating, roll coating, curtain coating, die coating, slit coating, gravure coating, or the like can be given.

When applying the varnish, the cloth made from long-fibers of a liquid crystal polymer may be previously placed on a support, on which the varnish is applied.

As examples of the support used, a resin film and a metal foil can be given.

As the resin film, a polyethylene terephthalate film, a polypropylene film, a polyethylene film, a polycarbonate film, a polyethylene naphthalate film, a polyallylate film, and a nylon film can be given. Among these films, a polyethylene terephthalate film and a polyethylene naphthalate film are preferable from the viewpoint of heat resistance, chemical resistance, removability, and the like.

As examples of the metal foil, a copper foil, an aluminum foil, a nickel foil, a chromium foil, a gold foil, a silver foil, and the like can be given. Of these, a copper foil, in particular, and electrolytic copper foil or a rolled copper foil is preferable from the viewpoint of excellent conductivity.

There are no specific limitations to the thickness of the support. The thickness of the support is usually 1 to 150 μm, preferably 2 to 100 μm, and still more preferably 5 to 80 μm.

The average surface roughness Ra of the support is usually 300 nm or less, preferably 150 nm or less, and more preferably 100 nm or less. If average surface roughness Ra of the support is too large, the average surface roughness Ra of the electrical insulating layer formed by curing the resulting composite resin molded article is too large, making it difficult to form a fine circuit pattern thereon as a conductive layer.

The composite resin molded article of the present invention can be obtained by drying the cloth made from long-fibers of a liquid crystal polymer impregnated with the varnish.

The conditions of drying the cloth made from long-fibers of a liquid crystal polymer impregnated with the varnish can be selected according to the type of the organic solvent. Specifically, the drying temperature is usually 20 to 300° C., and preferably 30 to 200° C. If the drying temperature is too high, the curing reaction may proceed and the composite resin molded article in an uncured state or a half-cured state may not be obtained. The drying time is usually from 30 seconds to one hour, and preferably from one minute to 30 minutes.

### (6) Flame Retardant

Although the composite resin molded article of the present invention possesses high flame retardancy, a flame retardant may be added in order to further increase the flame retardancy.

A flame retardant not containing halogen which generates only a small amount of toxic substances at the time of incineration is preferably used. As the specific examples of flame retardant not containing halogen, antimony compounds such as antimony trioxide, antimony pentoxide, and sodium antimonite; inorganic flame retardants such as aluminum hydroxide, magnesium hydroxide, zinc borate, guanidine sulfamate, zirconium compound, molybdenum compound, aluminum borate, and tin compounds; organometallic compounds such as ferrocene; and phosphorus-containing flame retardants such as phosphates, aromatic-condensed phosphates, phosphazene compounds, phosphorus-containing epoxy compounds, reactive phosphorus compounds, ammonium polyphosphate, melamine phosphate, melamine salts of polyphosphoric acid, melam salts of polyphosphoric acid, melem salts of polyphosphoric acid, complex melamine-melam-melem salts of polyphosphoric acid, red phosphorus, and phosphazene compounds can be given. Among these, magnesium hydroxide, aluminum hydroxide, phosphazene compounds, melamine phosphate, melamine salts of polyphosphoric acid, melam salts of polyphosphoric acid, and melem salts of polyphosphoric acid are preferable. In view of excellent capability of promoting heat resistance, moisture resistance, and flame retardance, magnesium hydroxide and complex melamine-melam-melem salts of polyphosphoric acid are particularly preferable.

### (7) Fillers and Additives

The composite resin molded article of the present invention may contain fillers and additives which may provide the composite resin molded article with desired performance according to the application, to the extent that the effect of the present invention is not adversely affected.

As the filler which can be used, carbon black, silica, alumina, barium titanate, talc, mica, glass beads, hollow glass balls, and the like are given.

Examples of the additives include a soft polymer, a heat-resistant stabilizer, a weather-resistant stabilizer, an antioxidant, a leveling agent, an antistatic agent, a slipping agent, an anti-blocking agent, an anticlouding agent, a lubricant, a dye, a pigment, a natural oil, a synthetic oil, a wax, an emulsion, a magnetic material, a dielectric property adjusting agent, a toughness agent, a laser processing promoter, and the like.

There are no specific limitations to the method for adding the optional components such as the above-mentioned flame retardants, fillers, and additives.

Usually, these are added to the curable resin composition, and preferably added together with the polymer (A), the curable agent (B), and the organic solvent when the above-mentioned varnish is prepared.

Although not particularly limited, the composite resin molded article of the present invention is preferably in the form of a film or a sheet. The thickness of the film or sheet is usually 1 to 150 μm, preferably 3 to 100 μm, and still more preferably 5 to 80 μm.

The composite resin molded article of the present invention has excellent flame retardancy, electric insulation properties, and crack resistance, and generates only a very small amount of toxic substances during incineration. Therefore, the composite resin molded article is suitable as a material for forming an electrical insulating layer of a laminate and a multilayer circuit board.

### 2) Cured Product

The cured product of the present invention is obtained by curing the above-mentioned composite resin molded article of the present invention.

Curing of the composite resin molded article is usually carried out by heating the composite resin molded article.

The curing conditions are suitably selected according to the type of the curing agent. The curing temperature is usually 30 to 400° C., preferably 70 to 300° C., and more preferably 100 to 200° C. The curing time is usually 0.1 to 5 hours, and preferably 0.5 to 3 hours. The method for heating is not particularly limited. For example, an electric oven may be used.

Prior to curing, it is preferable to cause the composite resin molded article to come in contact with a compound which has a metal conjugating capability and, after contact, to wash the composite resin molded article with a solvent which can dissolved such a compound having a metal conjugating capability. This step can produce a smooth surface of the composite resin molded article and promote adhesion with a metal film to be applied in the subsequent step.

As examples of the compound having a metal conjugating capability, imidazoles such as 1-(2-aminoethyl)-2-methylimidazole; pyrazoles; triazoles; and triazines can be given.

The cured product of the present invention can be obtained by curing the composite resin molded article of the present invention and has excellent flame retardancy, electric insulation properties, and crack resistance, and generates only a very small amount of toxic substances during incineration. Therefore, the cured product of the present invention is suitable as a material of an electrical insulating layer of a laminate and a multilayer circuit board.

### 3) Laminate

The laminate of the present invention is made by laminating a substrate having a conductive layer (I) on the surface and an electrical insulating layer made of the cured product of the present invention.

### (1) Substrate

The substrate used in the present invention has a conductive layer (1) on the surface of an electric insulating substrate.

The electrical insulating substrate is obtained by forming a curable resin composition containing a common electrical insulating material such as an alicyclic olefin polymer, an epoxy resin, a maleimide resin, an acrylic resin, a methacrylic resin, a diallyl phthalate resin, a triazine resin, polyphenyl ether, and glass.

### (2) Conductive Layer (I)

There are no specific limitations to the conductive layer (I). Usually, the conductive layer (I) is a layer containing wiring formed from an electric conductive material such as a conductive metal, and may further contain various circuits. There are no specific limitations to the constitution, thickness and the like of the wiring and the circuits.

As specific examples of the substrate having a conductive layer (I) on the surface, a printed circuit board, a silicon wafer substrate, and the like can be given. The thickness of the substrate having a conductive layer (I) on the surface is usually 10 μm to 10 mm, preferably 20 μm to 5 mm, and still more preferably 30 μm to 2 mm.

It is preferable that the surface of the conductive layer (I) of the substrate used in the present invention be pretreated to improve adhesion to the electrical insulating layer.

The pretreatment is carried out using a general method without specific limitations. If the conductive layer (I) is made of copper, for example, a method for roughening the surface of the conductive layer (I) by causing a strong alkali oxidizing solution to come in contact with surface of the conductive layer (I) to form a copper oxide layer on the surface of the conductive layer (I), a method for roughening by previously oxidizing the surface of the conductive layer (I) by the above method and reducing the oxidized layer with sodium borohydride, formalin, or the like, a method for roughening the surface of the conductive layer (I) by depositing a plate on the conductive layer (I), a method for roughening the surface of the conductive layer (I) by causing an organic acid to come in contact with the surface of the conductive layer (I) to dissolve out the boundary of copper particles, and a method for forming a primary layer on the conductive layer (I) using a thiol compound, a silane compound, or the like can be given.

Among these methods, the method for roughening the surface of the conductive layer (I) by causing an organic acid to come in contact with the surface of the conductive layer (I) to dissolve out the boundary of copper particles, and the method for forming a primary layer on the conductive layer (I) using a thiol compound, a silane compound, or the like are preferable from the viewpoint of ease of maintaining a fine wiring pattern shape.

### (3) Preparation of Laminate

The laminate of the present invention can be prepared by forming an electrical insulating layer by heat-press adhesion and curing of the composite resin molded article of the present invention on a substrate having a conductive layer (I) on the surface.

As a specific method for heat-press adhesion, a method for layering the composite resin molded article having a support on the above substrate having a conductive layer (I) so that the composite resin molded article may be in contact with the conductive layer (I) and heat-pressing (laminating) using a pressing machine such as a press laminator, a press, a vacuum laminator, a vacuum press, or a roll laminator, thereby forming a layer of the composite resin molded article on the conductive layer (I) can be given. The heat-press can bond the substrate and the composite resin molded article in such a manner that there is substantially no void in the interface between the conductive layer (I) on the surface of the substrate and the layer of the composite resin molded article. A metal foil, if used as the support, can increase the adhesion to the composite resin molded article layer. Thus, the metal foil can be used as both the support and the later-described conductive layer (II) of a multilayer circuit board.

The temperature of the heat-press operation is usually 30 to 250° C., and preferably 70 to 200° C., and the pressure is usually 10 to kPa to 20 MPa, and preferably 100 kPa to 10 MPa. The heat-press time is usually 30 seconds to five hours, and preferably one minute to three hours.

The heat-press operation is preferably carried out under reduced pressure in order to promote circuit pattern embedding properties and to inhibit generation of bubbles.

The pressure of the atmosphere in which the heat-press operation is carried out is usually from 100 kPa to 1 Pa, and preferably from 40 kPa to 10 Pa.

Curing of the composite resin molded article is usually carried out by heating the entire substrate comprising the conductive layer (I) on which the composite resin molded article has been formed. The curing can be carried out simultaneously with the heat-press operation. It is also possible first to heat-press using conditions under which the composite resin molded article is not cured, that is, at a comparatively low temperature, and then to cure the composite resin molded article.

It is also possible that two or more composite resin molded articles may be caused to contact and adhere to the conductive layer (I) of the substrate in order to increase the flatness of the electrical insulating later and to increase the thickness of the electrical insulating later.

### 4) Multilayer Circuit Board and Method for Manufacturing Thereof.

The multilayer circuit board of the present invention comprises a conductive layer (II) formed on the electrical insulating layer of the laminate of the present invention.

When a resin film is used as the support of the composite resin molded article in preparing the above-mentioned laminate, the multilayer circuit board of the present invention can be manufactured by removing the support and forming a conductive layer (II) on the electrical insulating layer by plating or the like. When a metal foil is used as the support of the composite resin molded article, the multilayer circuit board can be prepared by forming a conductive layer (II) by etching the metal foil in a form of a pattern using a common etching method. The former method is preferred in the present invention.

The method for manufacturing the multilayer circuit board of the present invention by forming the conductive layer (II) on the electrical insulating layer by the plating method will be specifically described below.

In manufacturing the multilayer circuit board, viaholes which penetrate the laminate are usually formed before forming the conductive layer (II) in order to connect the conductive layers in the multilayer circuit board.

The viaholes can be formed by a chemical treatment such as a photolithographic method or by a physical treatment such as drilling, a laser method, or plasma etching. Among these methods, the method for using a laser such as a carbon dioxide laser, an excimer laser, a UV-YAG laser, or the like is preferable due to the capability of forming the minute viaholes without reducing the characteristics of the electrical insulating layer.

Next, in order to improve the adhesion to the conductive layer (II), the surface of the electrical insulating layer is roughened by oxidation and adjusted to a desired average surface roughness.

The average surface roughness Ra of the electrical insulating layer in the present invention is 0.05 μm or more, but less than 0.3 μm, preferably 0.06 μm or more, but not more than 0.2 μm, and the surface ten point average roughness Rzjis is 0.3 μm or more, but less than 4 μm, preferably 0.5 μm or more, but not more than 2 μm.

Ra is a central line average roughness prescribed in JIS B0601-2001, and the surface ten point average roughness Rzjis is average roughness at ten points shown in Exhibit 1 to JIS B0601-2001.

The surface of an electrical insulating layer can be oxidized by causing the surface to come in contact with an oxidizing compound.

As the oxidizing compound can be used, known compounds having oxidation capabilities such as an inorganic peroxide and an organic peroxide, gases, and the like can be given. The inorganic peroxides and organic peroxides are particularly preferred due to the ease of controlling the surface average roughness of an electrical insulating layer.

As specific examples of the inorganic peroxide, a permanganate, a chromic anhydride, a dichromate, a chromate, a persulfate, an active manganese dioxide, an osmium tetroxide, hydrogen peroxide, periodide, and ozone can be given.

Specific examples of the organic peroxide include dicumyl peroxide, octanoyl peroxide, m-chloroperbenzoic acid, and peracetic acid.

There are no specific limitations to the method for oxidizing the surface of the electrical insulating layer using an inorganic peroxide or an organic peroxide. For example, a method for causing a solution of an oxidizing compound, prepared by dissolving the oxidizing compound in a suitable solvent to come in contact with the surface of the electrical insulating layer can be given.

There are no specific limitations to the method for causing a solution of an inorganic or organic oxidizing compound to come in contact with the surface of the electrical insulating layer. For example, a dipping method comprising dipping the electrical insulating layer in a solution of the oxidizing compound, a liquid loading method for loading the solution of the oxidizing compound on the insulating layer by surface tension, and a spraying method for spraying the solution of the oxidizing compound onto the substrate can be given.

The time and the temperature at which the solution of the inorganic oxidizing compound or organic oxidizing compound is caused to come in contact with the surface of the electrical insulating layer can be arbitrarily determined taking into consideration the concentration of the peroxide, form of the peroxide, and the method for casing the peroxide to come in contact with the surface of the electrical insulating layer. Such a temperature is usually 10 to 250° C., and preferably 20 to 180° C., and the time is usually 0.5 to 60 minutes, and preferably 1 to 30 minutes.

As the method for oxidizing using a gas, a reverse sputtering method and a plasma treatment in which a gas is radicalized or ionized such as corona discharge can be given. As examples of the gas, air, oxygen, nitrogen, argon, water, carbon disulfide, and carbon tetrachloride can be given.

When the gas used for oxidation is liquid at the treatment temperature, but is gaseous under reduced pressure, the oxidation treatment is carried out under reduced pressure.

When the gas used for oxidation is gaseous at the treating temperature and pressure, the oxidation treatment is carried out after increasing the pressure to a level at which the gas is radicalized or ionized.

The temperature or the time at which the plasma is caused to come in contact with the surface of the electrical insulating layer may be determined taking the type, flow rate, and the like of the gas into consideration. Such a temperature is usually 10 to 250° C., and preferably 20 to 180° C., and the time is usually 0.5 to 60 minutes, and preferably 1 to 30 minutes.

When the surface of the electrical insulating layer is oxidized using a solution of an oxidizing compound, it is preferable to add a polymer and an inorganic filler which are soluble in the solution of the oxidizing compound to the curable resin composition from which the electrical insulating layer is formed. Since the inorganic filler and the polymer (A) are dissolved after forming a fine island-like structure, it is easy to control the surface roughness of the above-mentioned insulating layer in the range mentioned above.

As examples of the polymer soluble in the solution of the oxidizing compound, a liquid epoxy resin, a polyester resin, a bismaleimide triazine resin, a silicone resin, a polymethyl methacrylate resin, natural rubber, a styrene rubber, an isoprene rubber, a butadiene rubber, a nitrile rubber, an ethylene rubber, a propylene rubber, a urethane rubber, a butyl rubber, a silicone rubber, a fluororubber, a norbornene rubber, and an ether rubber can be given.

There are no specific limitations to the amount of the polymer soluble in the solution of the oxidizing compound. The amount is usually in a range from 1 to 30 parts by weight, preferably from 3 to 25 parts by weight, and still more preferably from 5 to 20 parts by weight for 100 parts by weight of the polymer (A).

As examples of the inorganic filler soluble in the solution of the oxidizing compound, calcium carbonate, magnesium carbonate, barium carbonate, zinc oxide, titanium oxide, magnesium oxide, magnesium silicate, calcium silicate, zirconium silicate, hydrated alumina, magnesium hydroxide, aluminum hydroxide, barium sulfate, silica, talc, and clay can be given. Of these, calcium carbonate and silica are suitable for obtaining a finely roughened surface due to the capability of producing fine particles and being easily dissolved out using an aqueous solution in which the filler is soluble. An inorganic filler treated with a silane coupling agent or an organic acid such as stearic acid may be used.

The inorganic filler which can be added is preferably a nonconductive material which does not reduce the dielectric properties of the electrical insulating layer.

There are no specific limitations to the shape of the inorganic filler. Although the inorganic filler may be spherical, fibrous, tabular, or the like, fine particles are preferable in order to obtain a finely roughened surface.

The average particle diameter of the inorganic filler is usually 0.008 μm or more, but less than 2 μm, preferably 0.01 μm or more, but less than 1.5 μm, and particularly preferably 0.02 μm or more, but less than 1 μm. If the average particle diameter is too small, uniform adhesiveness may not be obtained when using a large substrate. If the average particle diameter is too large, on the other hand, an unduly roughened surface may be produced on the electrical insulating layer. A high density wiring pattern may not be obtained in such a case.

The amount of the inorganic filler soluble in the solution of the oxidizing compound is appropriately determined according to the degree of required adhesiveness, usually in a range from 1 to 80 parts by weight, preferably from 3 to 60 parts by weight, and still more preferably from 5 to 40 parts by weight for 100 parts by weight of the polymer (A).

The polymer and inorganic filler soluble in the solution of the oxidizing compound may be a part of a flame retardant adjuvant, heat-resistant stabilizer, dielectric-adjusting agent, or toughness-promoting agent to be optionally added to the curable resin composition of the present invention.

After the oxidation treatment, the surface of the electrical insulating layer is usually washed with water in order to remove the oxidizing compound. When a substance which cannot be removed only by washing with water adheres, the surface is further washed with a washing medium which can dissolve the substance, or the surface is caused to come in contact with another compound which can make the substance soluble in water before washing with water. For example, when an alkaline aqueous solution such as a potassium permanganate solution or a sodium permanganate solution is caused to come in contact with the electrical insulating layer, the treated surface is neutralized and reduced with an acidic aqueous solution such as a mixed solution of hydroxyamine sulfate and sulfuric acid in order to remove a film of manganese dioxide before washing with water.

After adjusting the average surface roughness by oxidizing the electrical insulating layer, a conductive layer (II) is formed on the surface of the electrical insulating layer and the inner wall surface of viaholes of the laminate.

Although the method for forming the conductive layer (II) is not particularly limited, a plating method is preferable in order to form a conductive layer (II) excelling in adhesiveness.

Although there are no particular limitations to the method for forming the conductive layer (II) by a plating method, a method for forming a thin film of metal by plating or the like on the electrical insulating layer, and growing the metal layer to form a thick plating may be employed.

When forming a thin film of metal by electroless plating, it is common to cause catalyst nuclei of silver, palladium, zinc, cobalt, or the like to adhere to the electrical insulating layer, before forming the thin film of metal on the surface of the electrical insulating layer.

The method for causing catalyst nuclei to adhere to the electrical insulating layer is not particularly limited. For example, a method for preparing a solution by dissolving a metal compound such as silver, palladium, zinc, or cobalt, or a salt or a complex of these metal compounds in water, an alcohol, or an organic solvent such as chloroform to a concentration of 0.001 to 10 wt % (the solution may optionally contain an acid, an alkali, a complexing agent, a reducing agent, etc.) and dipping the electrical insulating layer in the solution to reduce the metal can be used.

A common autocatalysis-type electroless plating solution may be used as the electroless plating solution used for the electroless plating method. There are no specific limitations to the type of the metal, reducing agent, complexing agent, pH, dissolved oxygen concentration, and the like.

For example, electroless plating solutions such as an electroless copper plating solution containing ammonium hypophosphate, hypophosphorous acid, ammonium hydrogenated boron, hydrazine, formalin, or the like as a reducing agent; an electroless nickel-phosphorus plating solution containing sodium hypophosphite as a reducing agent; an electroless nickel-boron plating solution containing dimethylamine borane as a reducing agent; an electroless palladium plating solution; an electroless palladium-phosphorus plating solution containing sodium hypophosphite as a reducing agent; an electroless gold plating solution; an electroless silver plating solution; and an electroless nickel-cobalt-phosphorus plating solution containing sodium hypophosphite as a reducing agent can be used.

After forming the thin film of metal, the surface of the substrate may be treated for rust proofing by causing the surface to come in contact with a rust proofing agent. After the formation, the formed thin film of metal may be heated to improve adhesiveness. The heating temperature is usually 50 to 350° C., and preferably 80 to 250° C.

Heating may be carried out while applying pressure. As a method for applying pressure, a physical method for pressing such as a method for using a heat-press machine, a heat-press roller, or the like can be given. The pressure to be applied is usually from 0.1 to 20 MPa, and preferably from 0.5 to 10 MPa. If a pressure in the above range is applied, high adhesion of the thin metal film with the electrical insulating layer can be ensured.

A resist pattern for plating is formed on the thin metal film obtained in this manner, and the plating is grown on the resist by wet plating such as electrolysis plating (thick plating). Then, after removing the resist, the thin metal film is etched conforming to the pattern to form a conductive layer (II). Therefore, the conductive layer (II) formed by this method usually consists of a patterned thin metal film and a plating grown on the thin metal film.

Further multilayering is possible by repeating the above-mentioned steps of forming the electrical insulating layer and the conductive layer (II) using the multilayer circuit board obtained in this manner as a new laminate, whereby a desired multilayer circuit board can be obtained.

The multilayer circuit board of the present invention is excellent in adhesiveness of the electrical insulating layer and the conductive layer (II). The peeling strength to remove the conductive layer (II) from the electrical insulating layer of the multilayer circuit board of the present invention measured according to JIS C6481 is usually 6 N/cm or more, and preferably 8 N/cm or more.

The multilayer circuit board of the present invention has excellent crack resistance. When the multilayer circuit board of the present invention is tested by the Erichsen test A method according to JIS Z2247, the Erichsen value, which is the distance which the punch moves from the crease holder surface at the time when a crack is produced on the surface of the substrate, is usually 4 mm or more, and preferably 5 mm or more.

Since the multilayer circuit board of the present invention has excellent electrical properties, it can be suitably used as a substrate for a semiconductor device such as a CPU and memory, as well as other surface-mounted components in electronic devices such as a computer and a cellular phone, as described later.

### 5) Electronic Device

The electronic device of the present invention is characterized by possessing the multilayer circuit board of the present invention.

As examples of the electronic device of the present invention, a cellular phone, a PHS, a notebook computer, a PDA (portable information terminal), a mobile videophone, a personal computer, a supercomputer, a server, a router, an LCD projector, an engineering workstation (EWS), a pager, a word processor, a television, a view finder-type or a monitor direct viewing-type videotape recorder, an electronic notebook, an electronic table-top calculator, a car navigator, a POS terminal, and a touch panel-equipped device can be given.

Since the electronic device of the present invention is equipped with the multilayer circuit board of the present invention, the electronic device possesses high performance and high quality.

### EXAMPLES

The present invention is described below in more detail by way of examples and comparative example, which are not intended to limit the present invention. In the examples and comparative examples, “part(s)” means “part(s) by weight” and “%” means “wt %” unless otherwise indicated.

The following definitions and methods of evaluation of various properties apply.

### (1) Number Average Molecular Weight (Mn) and Weight Average Molecular Weight (Mw)

The Mn and Mw were measured by gel permeation chromatography (GPC) using toluene or tetrahydrofuran as a developing solvent, and determined as polystyrene-reduced values.

### (2) Hydrogenation Rate of Polymer

The hydrogenation rate refers to a ratio of the number of moles of hydrogenated unsaturated bonds to the unsaturated bonds in the polymer before hydrogenation. The hydrogenation rate was determined by measuring the ¹H-NMR spectrum.

### (3) Content of Carboxyl Group and the Like in the Polymer

The content of the carboxyl group and the like refers to the ratio of the number of moles of the carboxyl group and the like to the total number of monomer units in the polymer, and was determined by ¹H-NMR spectrum measurement of the polymer.

### (4) Acid Value of Polymer

The acid number of the polymer (A) was determined by the method according to JIS K0070. Specifically, the polymer (A) was dissolved in THF and the solution was titrated with a solution of tetra-n-butylammonium hydroxide ((n-C₄H₉)₄N⁺OH⁻) of a predetermined concentration using phenolphthalein specified in JIS K 8001, 4.3, as an indicator. The acid number was determined as the amount (mg) of potassium hydroxide required for neutralizing the carboxyl group and the like contained in 1 g of the sample.

### (5) Glass Transition Temperature (Tg) of Polymer

The glass transition temperature (Tg) was measured by differential scanning calorimetry (DSC) at a rate of temperature increase of 10° C./min.

### (6) Volume Resistibility of Polymer

The volume resistibility was measured according to ASTM D257.

### (7) Surface Average Roughness (Ra) and Surface Ten Point Average Roughness (Rzjis)

The surface average roughness (Ra) and surface ten point average roughness (Rzjis) of the surface of the electrical insulating layer or the conductive layer (II) were determined as the central line average roughness Ra shown in JIS B0601-2001 and the surface ten point average roughness Rzjis shown in Exhibit 1 to JIS B0601-2001 based on the values measured at five points on a square area (20 μm×20 μm) using a non-contact-type optical surface form measuring device (“VK-8500”, a color laser microscope manufactured by KEYENCE CORP.).

### (8) Coefficient of Linear Expansion of Composite Resin Molded Article

A part of the composite resin molded article was cut and laid on one side of a rolled copper foil with a thickness of 75 μm. After removing the polyethylene terephthalate film of the support by peeling, the composite resin molded article was heated at 60° C. for 30 minutes and at 170° C. for 60 minutes under nitrogen atmosphere, thereby curing the composite resin molded article. Then, the entire rolled copper foil was removed by etching using a mixed solution of cupric chloride and hydrochloric acid to obtain a sheet-like formed article. A test specimen with a dimension of 5.95 mm in width, 15.4 mm in length, and 30 μm in thickness was cut out from the obtained sheet-like formed article. The coefficient of linear expansion was measured using a heat weight/differential heat analyzer (“TMA/SDTA840” manufactured by Mettler Toledo, Co.) and evaluated according to the following standard.

Good: Product with a coefficient of linear expansion of less than 25 ppm/° C.
Fair: Product with a coefficient of linear expansion of 25 ppm/° C. or more, but less than 40 ppm/° C.
Bad: Product with a coefficient of linear expansion of 40 ppm/° C. or more

### (9) Electrical Properties of Composite Resin Molded Article

A test specimen with a dimension of 2.6 mm in width, 80 mm in length, and 30 μm in thickness was cut out from the formed article obtained in the same manner as in (8). The relative dielectric constant and dielectric loss tangent at 10 GHz were measured using a hollow resonator perturbation method dielectric constant measuring device and evaluated according to the following standard.

Good: Product with a dielectric loss tangent of less than 0.01 and a relative dielectric constant of less than 2.8
Fair: Product with a dielectric loss tangent of less than 0.01 and a relative dielectric constant of 2.8 or more
Bad: Product with a dielectric loss tangent of 0.01 or more

### (10) Adhesion of Conductive Layer (II)

The peeling strength to remove the conductive layer (II) from the electrical insulating layer was measured according to JIS C6481 and evaluated according to the following standard.

Excellent: Product with an average peeling strength of more than 8 N/cm
Good: Product with an average peeling strength of more than 6 N/cm, but not more than 8 N/cm
Fair: Product with an average peeling strength of more than 4 N/cm, but not more than 6 N/cm
Bad: Product with an average peeling strength of less than 4 N/cm

### (11) Crack Resistance

The multilayer circuit board before plating was tested by the Erichsen test A method according to JIS Z2247 using a No. 2 test specimen. The Erichsen value, which is the distance which the punch moves from the crease holder surface at the time when a crack is produced on the surface of the substrate, was measured. The results were evaluated according to the following standard.

Good: Test specimen with an Erichsen value of 5 mm or more
Fair: Test specimen with an Erichsen value of 4 mm or more, but not more than 5 mm
Bad: Test specimen with an Erichsen value of less than 4 mm

### (12) Flame Retardancy

An internal layer substrate having a composite resin molded article layer was prepared in the same manner as in Example 1 using the core material of Example 1 (without a copper foil attached to the surface) as an internal layer substrate, and a composite resin molded article with a support obtained in an Example or a Comparative Example.

A test specimen was prepared by cutting the internal layer substrate having the composite resin molded article layer into the shape of a strip with a width of 13 mm and a length of 100 mm. The test specimen was exposed to the flame of a Bunsen burner according to the UL94V vertical combustibility test method. The flame was extinguished immediately after the test specimen was ignited, and the length of time that the test specimen was burning was measured. When the fire was extinguished, the test specimen was immediately exposed to the flame until reignited. The flame was extinguished immediately after the test specimen was reignited, and the length of time that the test specimen was burning was measured. Based on the results obtained, the flame retardancy was evaluated according to the following standard.

Good: Test specimen with the total of the first burning time and the second burning time of less than 20 seconds
Fair: Test specimen with the total of the first burning time and the second burning time of more than 20 seconds, but not more than 30 seconds
Bad: Test specimen with the total of the first burning time and the second burning time of more than 30 seconds or with the burning area reaching the top of the test specimen

### Production Example 1

8-Ethyl-tetracyclo[4.4.0.1^{2,5}.1^{7,10}]dodec-3-ene (hereinafter referred to as ETD) was polymerized by ring-opening polymerization using 1-butene as a molecular weight adjusting agent. The polymer was hydrogenated to obtain a hydrogenated ETD ring-opening polymer. The Mn of the hydrogenated ETD ring-opening polymer was 31,200, the Mw was 55,800, and the Tg was 140° C. The hydrogenation rate was 99% or more. 100 parts of the hydrogenated ETD ring-opening polymer, 40 parts of maleic anhydride, and 5 parts of dicumyl peroxide were dissolved in 250 parts of t-butylbenzene. The mixture was allowed to graft-react at 140° C. for six hours. The resulting reaction solution was poured into 1,000 parts of isopropyl alcohol to precipitate the reaction product. The precipitate was collected by filtration and dried at 100° C. for 20 hours under vacuum to obtain a hydrogenated ring-opening polymer a which is modified with maleic anhydride. The Mn of the modified hydrogenated ring-opening polymer a was 33,200, the Mw was 68,300, and the Tg was 170° C. The content of carboxyl group and the like was 25 mol %. The acid number was 132 mg KOH/g, and the volume resistibility was 1×10¹⁴ Ω·cm or more. The results are shown in Table 1.

### Production Example 2

A hydrogenated ETD ring-opening polymer with Mn of 43,100, Mw of 95,000, and Tg of 140° C. was obtained in the same manner as in Production Example 1 except for reducing the amount of 1-butene. The hydrogenation rate of this hydrogenated ring-opening polymer was 99% or more. A modified hydrogenated ring-opening polymer b was obtained in the same manner as in Production Example 1 by graft-bonding the resulting hydrogenated ETD ring-opening polymer. The results of measuring the properties of the modified hydrogenated ring-opening polymer b are shown in Table 1.

### Production Example 3

A hydrogenated ETD ring-opening polymer with an Mn of 123,300, Mw of 320,000, and Tg of 149° C. was obtained in the same manner as in Production Example 1 except that 1-butene was not added. The hydrogenation rate of this hydrogenated ring-opening polymer was 99% or more. 100 parts of the hydrogenated ETD ring-opening polymer, 45 parts of maleic anhydride, and 7 parts of dicumyl peroxide were dissolved in 500 parts of t-butylbenzene. The mixture was allowed to react (graft-bonding reaction) at 140° C. for six hours. A modified hydrogenated ring-opening polymer c was obtained in the same manner as in Example 1. The results of measuring the properties of the modified hydrogenated ring-opening polymer c are shown in Table 1.

### Production Example 4

A hydrogenated ETD ring-opening polymer with an Mn of 3,900, Mw of 5,700, and Tg of 107° C. was obtained in the same manner as in Production Example 1 except for increasing the amount of 1-butene. The hydrogenation rate of this hydrogenated ring-opening polymer was 99% or more. A modified hydrogenated ring-opening polymer d was obtained in the same manner as in Production Example 1 by graft-bonding reaction of the resulting hydrogenated ETD ring-opening polymer. The results of measuring the properties of the modified hydrogenated ring-opening polymer d are shown in Table 1.

### Production Example 5

A hydrogenated ETD ring-opening polymer with Mn of 15,600, Mw of 25,300, and Tg of 125° C. was obtained in the same manner as in Production Example 1 except for increasing the amount of 1-butene. The hydrogenation rate of this hydrogenated ring-opening polymer was 99% or more. A modified hydrogenated ring-opening polymer e was obtained in the same manner as in Production Example 1 by graft-bonding reaction of the resulting hydrogenated ETD ring-opening polymer, except for using 240 parts of maleic anhydride and 12 parts of dicumyl peroxide. The results of measuring the properties of the modified hydrogenated ring-opening polymer e are shown in Table 1.

### Production Examples 6 to 8

Modified hydrogenated ring-opening polymers f, g, and h were obtained in the same manner as in Production Example 1 except for using 27 parts, 51 parts, and 2 parts respectively of maleic anhydride in the graft-bonding reaction. The results of measuring the properties of the modified hydrogenated ring-opening polymers f, g, and h are shown in Table 1.

### Production Example 9

A pressure resistant glass vessel of which the internal atmosphere was replaced with nitrogen was charged with 77.3 parts of ETD, 22.7 parts of tetracyclo[4.4.0.1^{2,5}.1^{7,10}]-8-dodecene-3,4-dicarboxylic acid anhydride, 1.0 part of 1,5-hexadiene, 0.05 part of 1,3-dimethylimidazolidin-2-ylidene(tricyclohexylphosphine)benzylideneruthenium dichloride, and 400 parts of tetrahydrofuran. The mixture was allowed to react at 60° C. for two hours with stirring to obtain a ring-opening copolymer solution (solid content: approximately 20%). The polystyrene-reduced Mw and Mn of the ring-opening copolymer in this solution were 28,000 and 14,000 respectively.

A part of this ring-opening copolymer solution was transferred to an autoclave equipped with a stirrer and reacted at 120° C. under hydrogen pressure of 4 MPa for five hours to obtain a solution (solid content: approximately 20%) containing a hydrogenated copolymer (hydrogenation rate: 100%). 100 parts of the solution and 1 part of activated carbon powder in a heat resistant container was placed in an autoclave. The mixture was treated with hydrogen at 190° C. under hydrogen pressure of 4 MPa for three hours while stirring. Next, the solution was filtered through a filter made from a fluororesin with a pore size of 0.2 μm to separate the activated carbon, thereby obtaining a hydrogenated ring-opening copolymer solution. The solution was smoothly filtered. The solution was coagulated by pouring into isopropyl alcohol. The produced crumb was dried to obtain a hydrogenated ring-opening copolymer i. The results of measuring the properties of the hydrogenated ring-opening copolymer i are shown in Table 1.

TABLE 1

| | | | | | Modified hydrogenated | | | | | | |
|---|---|---|---|---|---|---|---|---|---|---|---|
| | | | | | ring-opening polymer or | | | | | | |
| | | Hydrogenated ring-opening | | | hydrogenated ring-opening | | | | Content of | | |
| | | polymer | | | copolymer | | | | carboxyl group | | Volume |
| | | | | Tg | | | | Tg | and the like | Acid number | resistibility |
| | | Mn | Mw | (° C.) | | Mn | Mw | (° C.) | (mol %) | (mg KOH/g) | (Ω · cm) |
| Production | 1 | 31,200 | 55,800 | 140 | a | 33,200 | 68,300 | 170 | 25 | 132 | 1 × 10¹⁴ or more |
| Example | 2 | 43,100 | 95,000 | 140 | b | 45,200 | 97,100 | 172 | 25 | 132 | 1 × 10¹⁴ or more |
| | 3 | 123,300 | 320,000 | 149 | c | 133,700 | 343,200 | 174 | 25 | 132 | 1 × 10¹⁴ or more |
| | 4 | 3,900 | 5,700 | 107 | d | 4,100 | 5,800 | 108 | 25 | 132 | 1 × 10¹⁴ or more |
| | 5 | 15,600 | 25,300 | 125 | e | 23,000 | 70,300 | 173 | 90 | 365 | 1 × 10¹⁴ or more |
| | 6 | 31,200 | 55,800 | 140 | f | 32,600 | 57,200 | 170 | 17 | 93 | 1 × 10¹⁴ or more |
| | 7 | 31,200 | 55,800 | 140 | g | 33,800 | 71,800 | 172 | 32 | 163 | 1 × 10¹⁴ or more |
| | 8 | 31,200 | 55,800 | 140 | h | 31,300 | 56,300 | 170 | 1 | 6 | 1 × 10¹⁴ or more |
| | 9 | — | — | — | i | 14,000 | 28,000 | 145 | 23 | 130 | 1 × 10¹⁴ or more |

### Production Example 10

A complex melam-melamine salt of polyphosphoric acid (“PMP-200”, a flame retardant filler manufactured by Nissan Chemical Industries, Ltd., weight average particle diameter: 3.2 μm) was dried at 120° C. for six hours under vacuum. A zirconia pot with a capacity of 250 parts by volume containing 360 parts of zirconia beads having a diameter of 0.3 mm filled therein was charged with 25 parts of the dried complex melam-melamine salt of polyphosphoric acid and a mixed dispersant consisting of 42.6 parts of dried xylene and 10.7 parts of dried cyclopentanone (as organic dispersants). The complex melam-melamine salt was ground for one hour using a planetary ball mill (“P-5” manufactured by Fritsch) at a centrifugal acceleration of 15.9 G (disc rotation (revolution speed): 360 rpm, pot rotation (rotation speed): 780 rpm), thereby obtaining a flame retardant slurry (weight average particle diameter: 0.51 μm).

### Example 1

100 parts of the modified hydrogenated ring-opening polymer a as a polymer (A) component, 40 parts of bisphenol A bis(propylene glycol glycidyl ether) ether as a curing agent (B) component, 5 parts of 2-[2-hydroxy-3,5-bis(α,α-dimethylbenzyl)phenyl]benzotriazole as a laser processing improver, 0.1 parts of 1-benzyl-2-phenylimidazole as a curing accelerator, and 10 parts of liquid polybutadiene (“Nisseki polybutadiene B-1000” manufactured by Nippon Petrochemicals Co., Ltd.) as a polymer soluble in an oxidation treatment liquid were dissolved in a mixed solvent of 215 parts of xylene and 54 parts of cyclopentanone to obtain a curable resin varnish.

A nonwoven fabric of a wholly aromatic polyester liquid crystal polymer (“VECRUS MBBK 14 FXSP” manufactured by Kuraray Co., Ltd., 250 mm×250 mm, thickness: 20 μm, weight per unit area: 14 g/m²) was placed on a polyethylene naphthalate film (support) (300 mm×300 mm, thickness: 40 μm, average surface roughness Ra: 0.08 μm). The varnish obtained above was applied to and impregnated in the nonwoven fabric of a liquid crystal polymer using a die coater. The nonwoven fabric was dried under nitrogen atmosphere at 80° C. for ten minutes to obtain a composite resin molded article with a support having a thickness of 32 μm and a liquid crystal polymer content of 55%.

An internal layer substrate having conductive layers (I) on the surface was prepared from a double-sided copper clad substrate (150 mm×150 mm, thickness: 0.8 mm) which was made from a core material, obtained by impregnating glass fibers with a varnish containing a glass filler and a halogen-free epoxy resin, and copper plantings with a thickness of 18 μm on both sides of the core material. The conductive layer (I) with wiring having a line width and an interval between the lines of 50 μm and a thickness of 18 μm was formed on the surface of the internal layer substrate by microetching using an organic acid. The composite resin molded article obtained above was cut into squares (150 mm×150 mm) and attached to each side of the internal layer substrate so that the complex resin molded article was on the inside and the support was on the outside.

The complex resin molded article was bonded to the internal layer substrate by heating at 110° C. under a pressure of 1.0 MPa for 300 seconds using a vacuum laminating apparatus, having pressing plates made of heat-resistant rubber on top and bottom, while reducing the atmosphere to 200 Pa (primary pressing), and further heating at 140° C. under a pressure of 1.0 MPa for 300 seconds using a vacuum laminating apparatus, having pressing plates made of heat-resistant rubber covered with a metal plate on top and bottom, while reducing the atmosphere to 200 Pa (secondary pressing). The support was removed from the internal layer substrate to obtain an internal layer substrate having a complex resin molded article layer.

The internal layer substrate was immersed in a 1.0% 1-(2-aminoethyl)-2-methylimidazole solution at 30° C. for 10 minutes, then in water at 25° C. for one minute, and any excess solution was removed by an air knife. The internal layer substrate was then allowed to stand in a nitrogen atmosphere at 170° C. for 60 minutes to cure the resin layer thereby forming an electrical insulating layer on the internal layer substrate. Viaholes for interlayer connection with a diameter of 30 μm were formed through the electrical insulating layer using a UV-YAG laser at the third harmonic to produce a multilayer circuit board with viaholes.

The multilayer circuit board with viaholes was immersed in a solution containing 60 g/l of permanganate and 28 g/l of sodium hydroxide at 70° C. for 10 minutes while swinging (swing-immersion). The multilayer circuit board was washed with water by swing-immersion in a water tank for one minute and in another water tank for one minute, and immersed in a solution containing 170 g/l of hydroxylamine sulfate and 80 g/l of sulfuric acid at 25° C. for five minutes for neutralization/reduction, followed by washing with water.

As a pre-plating process, the washed multilayer circuit board was immersed in a Pd salt-containing plating catalyst solution containing 200 ml/l of “ALCUP Activator MAT-1-A” (manufactured by Uemura & Co., Ltd.), 30 ml/l of “ALCUP Activator MAT-1-B” (manufactured by Uemura & Co., Ltd.), and 0.35 g/l of sodium hydroxide at 60° C. for five minutes. The multilayer circuit board was washed with water by swing-immersion in a water tank for one minute and in another water tank for one minute. The multilayer circuit board was then immersed in a solution containing 20 ml/l of “ALCUP Reducer MAB-4-A” (manufactured by Uemura & Co., Ltd.) and 200 ml/l of “ALCUP Reducer MAB-4-B” (manufactured by Uemura & Co., Ltd.) at 35° C. for three minutes, thereby reducing the plating catalyst. The plating catalyst was absorbed in this manner to obtain a pre-plated multilayer circuit board.

The average surface roughness (Ra) and surface ten point average roughness (Rzjis) of the outermost electric insulating layer and the crack resistance of the resulting multilayer circuit board were measured. The evaluation results are shown in Table 2.

Next, an electroless copper plating process was carried out by immersing the pre-plated multilayer circuit board in a solution containing 100 ml/l of “THRU-CUP PSY-1A” (manufactured by Uemura & Co., Ltd.), 40 ml/l of “THRU-CUP PSY-1B” (manufactured by Uemura & Co., Ltd.), and 0.2 mol/l of formalin at 36° C. for five minutes while blowing air into the solution.

The multilayer circuit board having a thin metal film layer formed by the electroless plating was washed by swing-immersion in a water tank for one minute, then in another water tank for one minute. The multilayer circuit board was dried and rust-proofed to obtain a multilayer circuit board having an electroless plating film formed on the surface.

A commercially available dry film photo resist was applied to the surface of the rust-proofed multilayer circuit board. A mask having a pattern corresponding to the pattern for evaluating the adhesiveness was applied to the dry film. The film was exposed and developed to obtain a resist pattern. The rust-proofing agent was removed by immersing the multilayer circuit board in a solution containing 100 g/l of sulfuric acid at 25° C. for one minute. Electrolytic copper plating was performed on a part without the resist to form an electrolytic copper plating film with a thickness of 18 μm. The resist pattern was stripped away with a removing solution. A wiring pattern made of the metal film and the electrolytic copper plating film was formed on the multilayer circuit board by etching with a mixed solution of copper (II) chloride and hydrochloric acid, thereby obtaining a multilayer circuit board with a layer of wiring on each surface. Finally, the multilayer circuit board was annealed at 170° C. for 30 minutes to obtain a multilayer printed wiring board.

Circuit pattern properties, insulating properties at a high temperature and high humidity, and crack resistance of the resulting multilayer circuit board were measured. The evaluation results are shown in Table 2.

### Example 2

A multilayer circuit board was produced in the same manner as in Example 1, except for using a modified hydrogenated ring-opening polymer b instead of the modified hydrogenated ring-opening polymer a. The same evaluation items as in Example 1 were measured for the resulting multilayer circuit board. The results are shown in Table 2.

### Example 3

A multilayer circuit board was produced in the same manner as in Example 1, except for using a modified hydrogenated ring-opening polymer f instead of the modified hydrogenated ring-opening polymer a and changing the amount of bisphenol A bis(propylene glycol glycidyl ether) ether to 27 parts to make the ratio of the equivalent of carboxylic anhydride and the equivalent epoxy the same as in Example 1.

The same evaluation items as in Example 1 were measured for the resulting multilayer circuit board. The results are shown in Table 2.

### Example 4

A multilayer circuit board was produced in the same manner as in Example 1, except for using a modified hydrogenated ring-opening polymer g instead of the modified hydrogenated ring-opening polymer a and changing the amount of bisphenol A bis(propylene glycol glycidyl ether) ether to 51 parts to make the ratio of the equivalent of carboxylic anhydride and the equivalent of epoxy the same as in Example 1.

The same evaluation items as in Example 1 were measured for the resulting multilayer circuit board. The results are shown in Table 2.

### Example 5

A multilayer circuit board was produced in the same manner as in Example 1, except for using a nonwoven fabric of a wholly aromatic polyester liquid crystal polymer which was compressed by a heat-press operation (“VECRUS MBBK 22 CXSP” manufactured by Kuraray Co., Ltd., weight per unit area: 22 g/m²) instead of the nonwoven fabric of a wholly aromatic polyester liquid crystal polymer (“VECRUS MBBK 14 FXSP” manufactured by Kuraray Co., Ltd).

The same evaluation items as in Example 1 were measured for the resulting multilayer circuit board. The results are shown in Table 2.

### Example 6

A multilayer circuit board was produced in the same manner as in Example 1, except for using a modified hydrogenated ring-opening polymer i instead of the modified hydrogenated ring-opening polymer a and changing the amount of 1-benzyl-2-phenylimidazole to 0.3 parts and the amount of bisphenol A bis(propylene glycol glycidyl ether) ether to 37 parts to make the ratio of the equivalent of carboxylic anhydride and the equivalent of epoxy the same as in Example 1.

The same evaluation items as in Example 1 were measured for the resulting multilayer circuit board. The results are shown in Table 2.

### Example 7

A multilayer circuit board was produced in the same manner as in Example 1, except for adding 20 parts of condensed phosphate (“PX-200” manufactured by Daihachi Chemical Industry Co., Ltd.), 63 parts of the flame retardant slurry obtained in Production Example 10, and 3 parts of “ADK STAB FP-2200” (manufactured by ADEKA Corporation) as a flame retardant, and 30 parts of “Admafine silica SO-E5” (manufactured by Admatechs) as a filler, for preparing a curable resin varnish.

The same evaluation items as in Example 1 were measured for the resulting multilayer circuit board. The results are shown in Table 2.

### Comparative Examples 1 and 2

Multilayer circuit boards were produced in the same manner as in Example 1, except for using a modified hydrogenated ring-opening polymer c (Comparative Example 1) or a modified hydrogenated ring-opening polymer d (Comparative Example 2) instead of the modified hydrogenated ring-opening polymer a.

The same evaluation items as in Example 1 were measured for the resulting multilayer circuit boards. The results are shown in Table 2.

### Comparative Example 3

A multilayer circuit board was produced in the same manner as in Example 1, except for using a modified hydrogenated ring-opening polymer h instead of the modified hydrogenated ring-opening polymer a and changing the amount of bisphenol A bis(propylene glycol glycidyl ether) ether to 2 parts to make the ratio of the equivalent of carboxylic anhydride and the equivalent of epoxy the same as in Example 1.

The same evaluation items as in Example 1 were measured for the resulting multilayer circuit board. The results are shown in Table 2.

### Comparative Example 4

A multilayer circuit board was produced in the same manner as in Example 1, except for using a modified hydrogenated ring-opening polymer e instead of the modified hydrogenated ring-opening polymer a and changing the amount of bisphenol A bis(propylene glycol glycidyl ether) ether to 144 parts to make the ratio of the equivalent of carboxylic anhydride and the equivalent of epoxy the same as in Example 1.

The same evaluation items as in Example 1 were measured for the resulting multilayer circuit board. The results are shown in Table 2.

### Comparative Example 5

A composite resin molded article and an internal layer substrate having the composite resin molded article layer were produced in the same manner as in Example 1, except for using 100 parts of an epoxy resin which was a carboxyl-group-free polymer (“Epicoat 1000” manufactured by Japan Epoxy Resins Co., Ltd.) instead of the modified hydrogenated ring-opening polymer a and adding 5 parts of dicyandiamide. A multilayer circuit board was produced in the same manner as in Example 1 except for using this internal layer substrate having the composite resin molded article layer and not immersing the board in the solution of 1-(2-aminoethyl)-2-methylimidazole.

The same evaluation items as in Example 1 were measured for the resulting multilayer circuit board. The results are shown in Table 2.

TABLE 2

| | | | | | | Surface | | | | | | |
|---|---|---|---|---|---|---|---|---|---|---|---|---|
| | | | | Long-fibers | Average | ten point | | | | | | |
| | | | | of liquid | surface | average | Linear | | | | | |
| | | | Flame | crystal | roughness | roughness | expansion | Electrical | | | Crack | Flame |
| | | Polymer | retardant | polymer | Ra (μm) | Rzjis (μm) | coefficient | properties | Adhesion | Patterning | resistance | retardancy |
| Example | 1 | a | Not added | A | 0.09 | 1.85 | Good | Good | Excellent | Good | Good | Good |
| | 2 | b | Not added | A | 0.08 | 1.73 | Good | Good | Excellent | Good | Good | Good |
| | 3 | f | Not added | A | 0.07 | 1.59 | Good | Good | Excellent | Good | Good | Good |
| | 4 | g | Not added | A | 0.10 | 1.98 | Good | Good | Excellent | Good | Good | Good |
| | 5 | a | Not added | B | 0.09 | 1.77 | Good | Good | Excellent | Good | Good | Good |
| | 6 | i | Not added | A | 0.10 | 1.91 | Good | Good | Excellent | Good | Good | Good |
| | 7 | a | Added | A | 0.10 | 1.95 | Good | Good | Excellent | Good | Good | Good |
| Comparative | 1 | c | Not added | A | 1.32 | 3.98 | Good | Good | Bad | Bad | Bad | Good |
| Example | 2 | d | Not added | A | 0.09 | 1.91 | Good | Good | Bad | Bad | Bad | Bad |
| | 3 | h | Not added | A | 0.11 | 2.05 | Good | Good | Bad | Good | Bad | Bad |
| | 4 | e | Not added | A | 2.53 | 6.02 | Good | Fair | Fair | Good | Bad | Good |
| | 5 | Epoxy | Not added | A | 3.10 | 4.35 | Good | Bad | Bad | Bad | Bad | Bad |
| | | resin | | | | | | | | | | |

a to h: Modified hydrogenated ring-opening polymers a to h
i: Hydrogenated ring-opening copolymer i
A: VECRUS MBBK 14 FXSP
B: VECRUS MBBK 22 CXSP

As shown in Table 2, a multilayer circuit board which has high adhesion to the conductive layer (II), a low coefficient of linear expansion, excellent flame retardancy, electrical properties, and crack resistance, and a high density wiring pattern formed on the surface was produced by using the composite resin molded article of the present invention.

The average surface roughness (Ra) and surface ten point average roughness (Rzjis) of the pre-plated electric insulating layer were small, indicating excellent smoothness (Examples 1 to 7).

On the other hand, when the composite resin molded article prepared using a polymer having an excessively high weight average molecular weight (polymer c) was used, the surface roughness of the pre-plated electric insulating layer was too high. Although the flame retardancy of the resulting multilayer circuit board was good, the adhesiveness with the insulating layer (II) was poor, producing defects in the wiring. The crack resistance was also poor (Comparative Example 1).

When the composite resin molded article prepared using a polymer having an excessively low weight average molecular weight (polymer d) was used, the adhesiveness with the insulating layer (II) was poor producing defects in the wiring and large cracks, although the surface roughness of the pre-plated electric insulating layer was good (Comparative Example 2).

When the composite resin molded article prepared using a polymer having an excessively small content of carboxyl group and the like (polymer h) was used, the adhesiveness with the insulating layer (II), crack resistance, and flame retardancy were poor, although a good patterning was obtained (Comparative Example 3).

When the composite resin molded article prepared using a polymer having an excessively large content of carboxyl group and the like (polymer e) was used, the surface roughness was too high, and the electrical properties and crack resistance were poor, although a good patterning was obtained (Comparative Example 4).

When the composite resin molded article prepared using an epoxy resin not containing carboxyl group or carboxylic anhydride was used, the surface roughness of the pre-plated electric insulating layer was too high, and flame retardancy, electrical properties, crack resistance, and patterning were poor (Comparative Example 5).

### INDUSTRIAL APPLICABILITY

The composite resin molded article and the cured product thereof have excellent flame retardancy, electric insulation properties, and crack resistance, and generate only a very small amount of toxic substances during incineration.

The laminate and multilayer circuit board have a low thermal expansion and a high modulus of elasticity. The conductive layer exhibits high adhesion to a smooth electrical insulating layer, even if the conductive layer is formed on the electrical insulating layer by a plating method and thus possesses high reliability.

Since the multilayer circuit board of the present invention has excellent electrical properties, it can be suitably used as a substrate for a semiconductor device such as a CPU and memory, as well as other surface-mounted components in electronic devices such as a computer and a cellular phone.

1. A composite resin molded article produced by impregnating a cloth made from long fibers of a liquid crystal polymer with a curable resin composition which comprises a polymer (A) and a curing agent (B), the polymer (A) having a weight average molecular weight of 10,000 to 250,000 and containing 5 to 60 mol % of a carboxyl group or a carboxylic anhydride group.

2. The composite resin molded article according to claim 1, wherein the polymer (A) is an alicyclic olefin polymer.

3. The composite resin molded article according to claim 1, wherein the weight per unit area of the cloth made from long-fibers of a liquid crystal polymer is 3 to 55 g/m².

4. The composite resin molded article according to claim 1, wherein the liquid crystal polymer is a wholly aromatic polyester.

5. A method for manufacturing a composite resin molded article comprising impregnating a cloth made from long fibers of a liquid crystal polymer with a curable resin varnish which comprises a polymer (A) having a weight average molecular weight of 10,000 to 250,000 and containing 5 to 60 mol % of a carboxyl group or a carboxylic anhydride group, a curing agent (B), and an organic solvent, and drying the varnish-impregnated cloth.

6. A cured product produced by curing the composite resin molded article according to claim 1.

7. A laminate made by laminating a substrate having a conductive layer (I) on the surface and an electrical insulating layer made of the cured product according to claim 6.

8. A method for preparing the laminate according to claim 7 comprising forming an electrical insulating layer on a substrate having a conductive layer (I) on the surface by causing the composite resin molded article to adhere to the substrate by heat-pressing.

9. A multilayer circuit board comprising a conductive layer (II) formed on the electrical insulating layer of the laminate according to claim 7.

10. A method for manufacturing the multilayer circuit board according to claim 9 comprising a step of forming a conductive layer (II) on the electrical insulating layer of the laminate by a plating method.

11. An electronic device comprising the multilayer circuit board according to claim 9.
